(19) United States
(12) Patent Application Publication
(10) Pub. No.: US 2014/0191290 A1
(43) Pub. Date: Jul. 10, 2014

(54) SOLID-STATE IMAGING ELEMENT

(71) Applicants: Daisuke Funao, Osaka (JP); Takefumi Konishi, Osaka (JP)

(72) Inventors: Daisuke Funao, Osaka (JP); Takefumi Konishi, Osaka (JP)

(73) Assignee: SHARP KABUSHIKI KAISHA, Osaka (JP)

(21) Appl. No.: 14/240,186

(22) PCT Filed: Jul. 24, 2012
(86) PCT No.: PCT/JP2012/068649

§ 371 Date: Feb. 21, 2014

(30) Foreign Application Priority Data
Aug. 24, 2011 (JP) 2011-182160

(51) Int. Cl. H01L 27/146

(52) U.S. Cl. CPC H01L 27/14643; H01L 27/1463
USPC 257/231

(57) ABSTRACT

Provided is a solid-state imaging element that effectively reduces 1/f noise from a signal output from a source-follower transistor. The solid-state imaging element includes a first conductivity type substrate 10, a photodiode in which carriers are accumulated in a second conductivity type accumulation region, the second conductivity type being different from the first conductivity type, a source-follower transistor 15 which has a gate electrode 151 electrically connected to a floating diffusion region accumulated with the carriers read out from the photodiode and which is provided with a second conductivity type buried channel, and an element separator 21 which is provided around an active region of the photodiode and the source-follower transistor 15. The buried channel of the source-follower transistor 15 is formed away from a sidewall of the element separator 21.

### TECHNICAL FIELD

The present invention relates to a solid-state imaging element which is represented by a CMOS (Complementary Metal Oxide Semiconductor) image sensor.

### BACKGROUND ART

Since a CMOS image sensor can perform a high-speed operation and has smaller power consumption as compared with a CCD image sensor, the CMOS image sensor is mounted on various electronic devices having an imaging function, such as a digital video camera, a digital still camera, a surveillance camera, a scanner, a facsimile, a television phone, and a camera-equipped mobile phone.

The CMOS image sensor includes an amplifier (a source-follower transistor) in each pixel circuit, and the source-follower transistor amplifies and outputs a signal based on a potential obtained by photoelectric conversion of a photodiode. However, the signal amplified by the source-follower transistor includes noise in some cases. Specifically, 1/f noise (flicker noise) may be included in the signal which is output from the source-follower transistor. The 1/f noise is random noise which is generated due to irregular variation of a resistance because carriers (electrons or holes) are trapped and discharged in the level of the interface of a gate insulating film of the source-follower transistor.

The 1/f noise can be reduced by increasing a gate width of the source-follower transistor (by increasing a gate capacitance). However, due to demand for miniaturization and the like of a pixel circuit, it is difficult to increase the gate width until the 1/f noise is sufficiently reduced.

Thus, in Patent Documents 1 and 2, for example, there are proposed solid-state imaging elements that reduce the 1/f noise by causing carriers to pass through a position away from a gate insulating film by forming a buried channel in the source-follower transistor.

Meanwhile, around elements in the pixel circuit, an element separator for isolating the respective elements is provided in order to prevent formation and the like of parasitic elements. The element separator is also provided around the photodiode, but this causes a problem in that a dark current may be generated by contact of a depletion layer of the photodiode with an interface state of the element separator.

The dark current can be reduced by providing the element separator at a position sufficiently away from the photodiode. However, due to the demand for miniaturization and the like of the pixel circuit, it is difficult to provide the element separator at a position away from the photodiode where the dark current is sufficiently reduced.

Therefore, in Patent Document 3, for example, there is provided a solid-state imaging element that reduces the dark current, by forming an impurity layer of high concentration around the element separator which is provided around the photodiode.

### PRIOR ART DOCUMENTS

### Patent Documents

Patent Document 1: JP 2005-286168 A

Patent Document 2: JP 2006-120679 A

Patent Document 3: JP 2008-91702 A

### DISCLOSURE OF THE INVENTION

### Problem to be Solved by the Invention

The element separator described above is formed not only around the photodiode but also near the source-follower transistor. Because crystallinity of the interface of the element separator is likely to become poor, a level where carriers are trapped and discharged is likely to be formed. Therefore, when a channel of the source-follower transistor is spread to the interface of the element separator, the 1/f noise caused by the trapping and discharging of the carriers in the interface is generated, which causes a problem.

Therefore, an object of the present invention is to provide a solid-state imaging element that effectively reduces the 1/f noise from a signal which is output from the source-follower transistor.

### Means for Solving the Problem

To achieve the above object, provided is a solid-state imaging element including:

a first conductivity type substrate;

a photodiode which is formed on the substrate, and in which carriers generated by photoelectric conversion are accumulated in a second conductivity type accumulation region, the second conductivity type being different from the first conductivity type;

a source-follower transistor which is formed on the substrate, and which has a gate electrode electrically connected to a floating diffusion region accumulated with the carriers read out from the photodiode and which is provided with a second conductivity type buried channel; and

an element separator which is formed on the substrate, and which is provided around an active region of at least the photodiode and the source-follower transistor, wherein

the buried channel of the source-follower transistor is formed away from a sidewall of the element separator.

The “first conductivity type” and the “second conductivity type” refer to a p-type and an n-type. For example, when the “first conductivity type” is the p-type, the “second conductivity type” is the n-type, and when the “first conductivity type” is the n-type, the “second conductivity type” is the p-type. The “first conductivity type substrate” indicates that a portion where an element structure of the substrate is formed is the first conductivity type. The “first conductivity type substrate” is not limited to a substrate in which a whole substrate is the first conductivity type, but naturally includes a substrate in which a well is the first conductivity type (for example, a substrate in which a first conductivity type well is formed by injecting a first conductivity type impurity into a substrate in which the whole substrate is the second conductivity type).

Further, in the solid-state imaging element having the above characteristics, the buried channel of the source-follower transistor is preferably formed within a channel formation region provided by injecting a second conductivity type impurity into a surface of the first conductivity type substrate, and

a concentration of a first conductivity type impurity injected into a side region of the element separator is at a level of canceling a second conductivity type region included in the channel formation region.

In this case, spreading of the channel formation region can be suppressed. Therefore, a buried channel away from the sidewall of the element separator can be accurately formed. Further, generation of the dark current in the photodiode can be suppressed.

The channel formation region is a region provided by injecting a second conductivity type impurity into the surface of the first conductivity type substrate, and includes the second conductivity type region into which the second conductivity type impurity is injected and the first conductivity type region immediately below the second conductivity type region. Further, the buried channel is formed near the boundary between the second conductivity type region and the first conductivity type region.

Further, in the solid-state imaging element having the above characteristics, it is preferable that the concentration of the first conductivity type impurity injected into the side region of the element separator is at least two times the concentration of the second conductivity type impurity injected into the second conductivity type region included in the channel formation region of the source-follower transistor.

In this case, the buried channel away from the sidewall of the element separator can be formed more accurately.

Further, in the solid-state imaging element having the above characteristics, it is preferable that the first conductivity type impurity is injected into an outermost surface of the channel formation region of the source-follower transistor.

In this case, a channel potential in a conducting state near the surface of the substrate becomes lower, and a position at which the channel potential in the conducting state is the highest becomes deeper. Therefore, a buried channel which is buried more effectively can be formed in the source-follower transistor.

Further, in the solid-state imaging element having the above characteristics, it is preferable that the first conductivity type impurity is also injected into a lower region of the element separator.

This structure can be obtained by injecting the first conductivity type impurity prior to the formation of the element separator, for example.

Further, it is preferable that the solid-state imaging element having the above characteristics further includes: a transfer transistor which is formed on the substrate, and which has the accumulation region as a source and the floating diffusion region as a drain; and a reset transistor which is formed on the substrate, and which has the floating diffusion region as a source and a predetermined potential as a drain.

Further, in the solid-state imaging element having the above characteristics, it is preferable that the reset transistor is provided with a second conductivity type buried channel.

In the reset transistor, reset noise may be generated due to variation in a threshold voltage caused by the injection of the first conductivity type impurity into the side region of the element separator. However, a threshold voltage is adjusted by injecting a second conductivity type impurity similarly to the source-follower transistor, so that the reset noise can be suppressed.

By the injection of the second conductivity type impurity, the reset transistor may become a depletion type transistor. Even in this case, by appropriately adjusting the potential applied to a back gate or the like, the reset transistor can be set to the non-conducting state in a desired bias state.

Further, in the solid-state imaging element having the above characteristics, it is preferable that a separation direction of the source and the drain of the transfer transistor is different from a separation direction of the source and the drain of the source-follower transistor.

In this case, by appropriately selecting an injection direction of the first conductivity type impurity in the side region of the element separator, it is possible to partially control the concentration of the first conductivity type impurity injected into each of the vicinities of the transfer transistor and the source-follower transistor.

Further, it is preferable that the solid-state imaging element having the above characteristics further includes a selection transistor in which the drain is shared with the source of the source-follower transistor or the source is shared with the drain of the source-follower transistor.

Further, in the solid-state imaging element having the above characteristics, it is preferable that the selection transistor is provided with a second conductivity type buried channel.

Further, in the solid-state imaging element having the above characteristics, it is preferable that the element separator is an STI (Shallow Trench Isolation) including at least one of an oxide and a nitride.

Since the STI is a structure that extends in a depth direction of the substrate, it is highly necessary to suppress spreading of the buried channel. Therefore, when the above characteristics are employed in the solid-state imaging element having the STI, the obtained effect of reducing the 1/f noise becomes large.

Further, in the solid-state imaging element having the above characteristics, it is preferable that a gate electrode of at least one transistor provided with the buried channel is formed such that an end part of the gate electrode recedes from a position immediately above the element separator.

In this case, since the potential applied to the gate electrode is hardly applied to the vicinity of the element separator, the buried channel to be formed hardly spreads to the vicinity of the element separator. Therefore, it is possible to effectively reduce the 1/f noise.

Further, in the solid-state imaging element having the above characteristics, it is preferable that a gate insulating film that is provided immediately below a gate electrode of at least one transistor provided with the buried channel is formed such that a thickness of a portion near the element separator is larger than a thickness of a portion away from the element separator.

In this case, since the potential applied to the gate electrode is hardly applied to the vicinity of the element separator, the buried channel to be formed hardly spreads to the vicinity of the element separator. Therefore, it is possible to effectively reduce the 1/f noise.

### Effect of the Invention

According to the solid-state imaging element having the above characteristics, a buried channel which is away from a sidewall of the element separator is formed in the source-follower transistor. Therefore, by suppressing the influence of the level of a surface of the substrate (for example, the interface of the gate insulating film) and the interface of the element separation surface, it is possible to effectively reduce the 1/f noise from the signal output from the source-follower transistor.

### BRIEF DESCRIPTION OF THE DRAWINGS

FIG. 1 is a circuit diagram showing a schematic configuration example of a pixel circuit provided in a solid-state imaging element according to an embodiment of the present invention.

FIG. 2 is a schematic plan view showing a schematic structure example of the pixel circuit shown in FIG. 1.

FIG. 3 is a main-part cross-sectional perspective view showing an example of a structure of a source-follower transistor and a surrounding thereof.

FIG. 4 is a cross-sectional view showing a cross section perpendicular to an X direction of the source-follower transistor.

FIG. 5 is a cross-sectional view showing a cross section perpendicular to a Y direction of the source-follower transistor.

FIG. 6 is a cross-sectional view of a substrate showing an example of a method of injecting a p-type impurity into a surrounding region of an element separator.

FIG. 7 is a plan view of the substrate showing the example of the method of injecting the p-type impurity into the surrounding region of the element separator.

FIG. 8 is a cross-sectional view of the substrate showing another example of the method of injecting the p-type impurity into the surrounding region of the element separator.

FIG. 9 is a cross-sectional view showing another example of the structure of the source-follower transistor.

FIG. 10 is a main-part cross-sectional perspective view showing another example of the structure of the source-follower transistor.

FIG. 11 is a main-part cross-sectional perspective view showing another example of the structure of the source-follower transistor.

FIG. 12 is a schematic plan view showing another example of the schematic structure of the pixel circuit.

### MODE FOR CARRYING OUT THE INVENTION

<<Pixel Circuit>>

<Overall Outline>

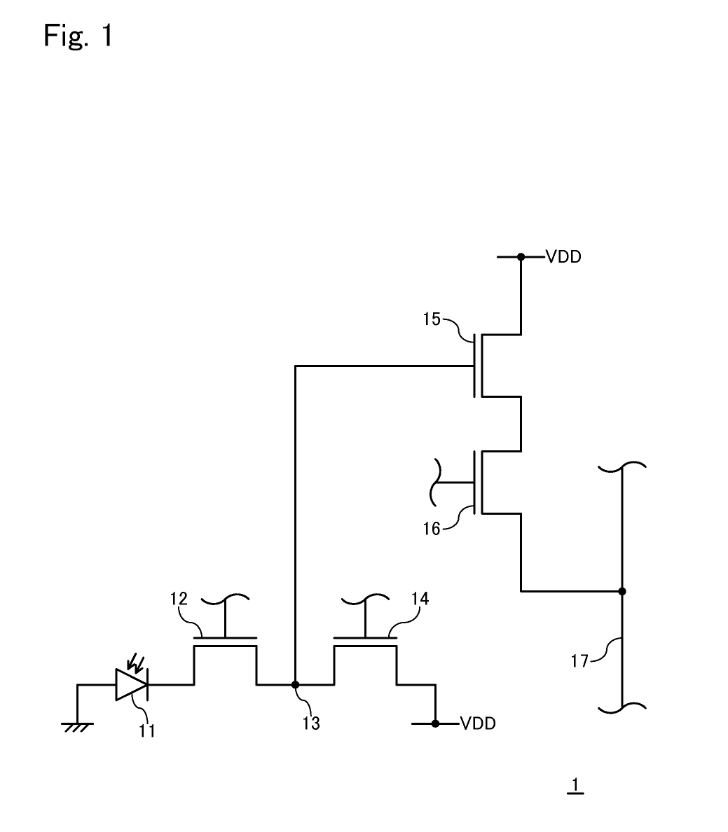

First, a schematic configuration example, a schematic operation example, and a schematic structure example of a pixel circuit provided in a solid-state imaging element (CMOS image sensor) according to an embodiment of the present invention will be described with reference to the drawings. FIG. 1 is a circuit diagram showing the schematic configuration example of the pixel circuit provided in the solid-state imaging element according to the embodiment of the present invention.

As shown in FIG. 1, a pixel circuit 1 includes a photodiode 11 in which an anode is grounded and which generates carriers by photoelectric conversion, a transfer transistor 12 in which a source is connected to a cathode of the photodiode 11, a floating diffusion region 13 connected to a drain of the transfer transistor, a reset transistor 14 in which a source is connected to the floating diffusion region 13 and a drain is supplied with a power supply potential VDD, a source-follower transistor 15 in which a drain is supplied with the power supply potential VDD and a gate electrode is electrically connected to the floating diffusion region 13, a selection transistor 16 in which a drain is connected to a source of the source-follower transistor 15, and a signal line 17 to which a source of the selection transistor 16 is connected.

For specific description, a case where carriers in the pixel circuit 1 are electrons is illustrated. Specifically, there is illustrated a case where each element constituting the pixel circuit 1 is formed on a p-type substrate, an accumulation region of carriers (electrons) of the photodiode 11 is the n-type accumulation region, and a channel formed in each of the transfer transistor 12, the reset transistor 14, the source-follower transistor 15, and the selection transistor 16 is the n-type channel.

The “p-type substrate” indicates a substrate in which a portion provided with the element structure is the p-type. The “p-type substrate” is not limited to a substrate in which a whole substrate is the p-type, but naturally includes a substrate in which a well is the p-type (for example, a substrate in which a p-type well is formed by injecting a p-type impurity into a substrate in which the whole substrate is the n-type). However, in each figure referred to in the following description, the substrate is illustrated as if the whole substrate is the p-type.

Si can be used as a material of the substrate. In this case, boron or the like can be used as a p-type impurity. Also in this case, phosphorus or arsenic can be used as an n-type impurity. Further, these impurities can be injected into a substrate 10 by applying a method such as ion implantation, for example. For specific description, a case of injecting an impurity by ion implantation will be illustrated below.

Next, with reference to FIG. 1, a schematic operation example of the pixel circuit 1 will be described. First, when light enters the photodiode 11, electrons and holes are generated by photoelectric conversion, and the electrons are accumulated in an n-type accumulation region. At this time, the transfer transistor 12 is set to a non-conducting state based on application of a low-level potential to the gate electrode.

Thereafter, when a high-level potential is applied to the gate electrode of the transfer transistor 12, the transfer transistor 12 is set to a conducting state, and the electrons accumulated in the accumulation region of the photodiode 11 are read out to the floating diffusion region 13. Thus, a potential of the floating diffusion region 13 becomes a potential corresponding to the number of electrons read out from the photodiode 11 (i.e., an amount of incident light).

However, because the reset transistor 14 is set to the conducting state based on the application of the high-level potential to the gate electrode of the reset transistor 14 before the electrons are read out to the floating diffusion region 13 from the photodiode 11, it is assumed that the floating diffusion region 13 is set (initialized) to a predetermined potential in advance. Thus, the potential of the floating diffusion region 13 after the electrons are read out from the photodiode 11 is lowered from the predetermined potential by a magnitude corresponding to the number of read-out electrons.

When the selection transistor 13 is set to the conducting state after a high-level potential is applied to the gate electrode of the selection transistor, the source-follower transistor 15 amplifies the signal based on the potential of the floating diffusion region 13 applied to the gate electrode. The signal amplified by the source-follower transistor 15 is output to the signal line 17 via the selection transistor 16.

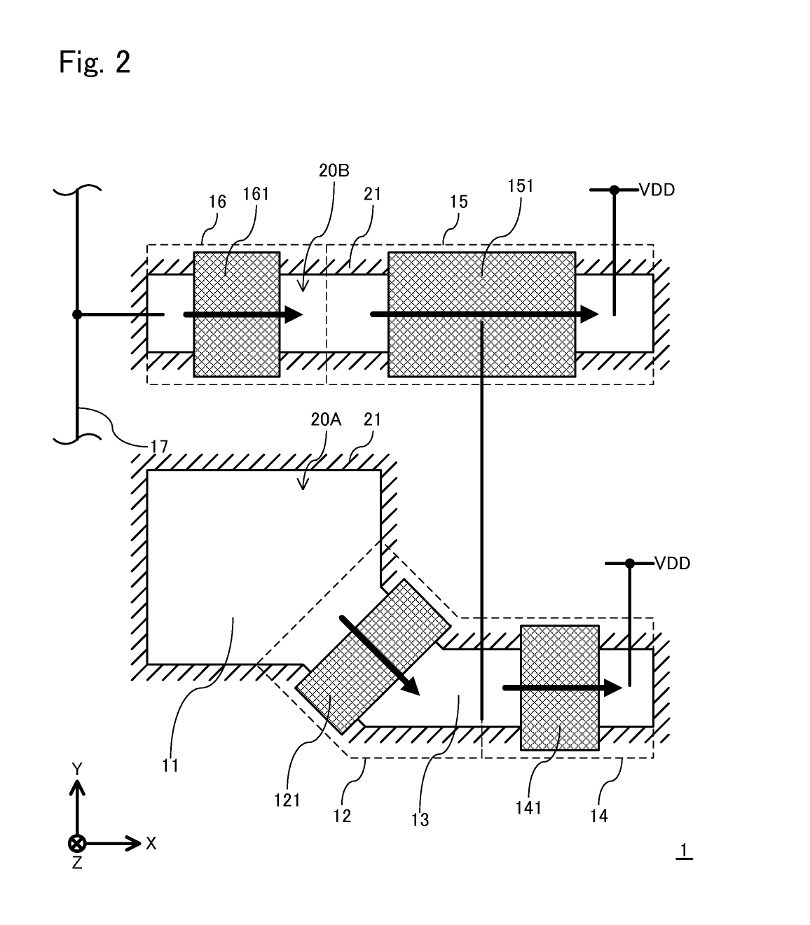

Next, with reference to FIG. 2, a schematic structure example of the pixel circuit 1 will be described. FIG. 2 is a schematic plan view showing a schematic structure example of the pixel circuit shown in FIG. 1. FIG. 2 is a plan view seen from a surface side of the substrate.

In FIG. 2, directions to which electrons move in the transistors 12, and 14 to 16 (directions to which the source and the drain are separated) are indicated by thick arrows. Further, in FIG. 2, gate electrodes 121, 141, 151, and 161 of the transistors 12, and 14 to 16 (for example, n-type polysilicon) are shown as regions marked with cross-hatching. Further, in FIG. 2, a wiring for supplying the power-supply potential VDD to the drain of the reset transistor 14, a wiring for connecting the source of the reset transistor 14 and the gate electrode 151 of the source-follower transistor 15, a wiring for supplying the power supply potential VDD to the drain of the source-follower transistor 15, and a wiring for connecting the source of the selection transistor 16 and the signal line 17 are shown respectively by thick lines for simplification.

As shown in FIG. 2, an element separator 21 is provided around active regions 20A and 20B provided with element structures of the photodiode 11 and the transistors 12, and 14 to 16. Specifically, the element separator 21 is provided around the active region 20A which is provided with a structure formed by connecting the photodiode 11, the transfer transistor 12, the floating diffusion region 13, and the reset transistor 14, and the active region 20B which is provided with a structure formed by connecting the source-follower transistor 15 and the selection transistor 16. The element separator 21 can be formed on the whole substrate excluding the active regions 20A and 20B, and particularly in FIG. 2, portions formed near the active regions 20A and 20B are shown by hatched lines. In FIG. 2, although the gate electrodes 121, 141, 151, and 161 are shown to only exist near positions immediately above the active regions 20A and 20B, the gate electrodes may be actually extended more.

The photodiode 11, the transfer transistor 12, and the reset transistor 14 which are included in the active region 20A have a shared diffusion layer. Specifically, the accumulation region of the photodiode 11 becomes the source of the transfer transistor 12. The drain of the transfer transistor 12 becomes the floating diffusion region 13, and also becomes the source of the reset transistor 14. Similarly, the source-follower transistor 15 and the selection transistor 16 which are included in the active region 20B also have a shared diffusion layer. Specifically, the source of the source-follower transistor 15 is shared with the drain of the selection transistor 16.

Further, in each of the reset transistor 14, the source-follower transistor 15, and the selection transistor 16, electrons move toward the same direction (hereinafter, an X direction). On the other hand, in the transfer transistor 12, electrons move toward a direction different from the X direction (a direction inclined by 45 degrees to the X direction in the example shown in FIG. 2).

The element separator 21 is also provided near a portion where a channel is formed in each of the transistors 12, and 14 to 16 (portions of arrows in the figure). The two active regions 20A and 20B are provided side by side in a direction perpendicular to the X direction (hereinafter, a Y direction). Here, the X direction and the Y direction are directions parallel to a main surface of the substrate. In the following, a direction perpendicular to the X direction and the Y direction (i.e., a direction perpendicular to the main surface of the substrate, a depth direction) is referred to as a Z-direction.

The element separator 21 is an STI, for example, and includes at least one of an oxide and a nitride as an insulator. Specifically, the element separator 21 is formed by embedding SiO₂ as an oxide of Si into a trench formed by digging the trench in the Z direction from the surface of the substrate.

<Source-Follower Transistor>

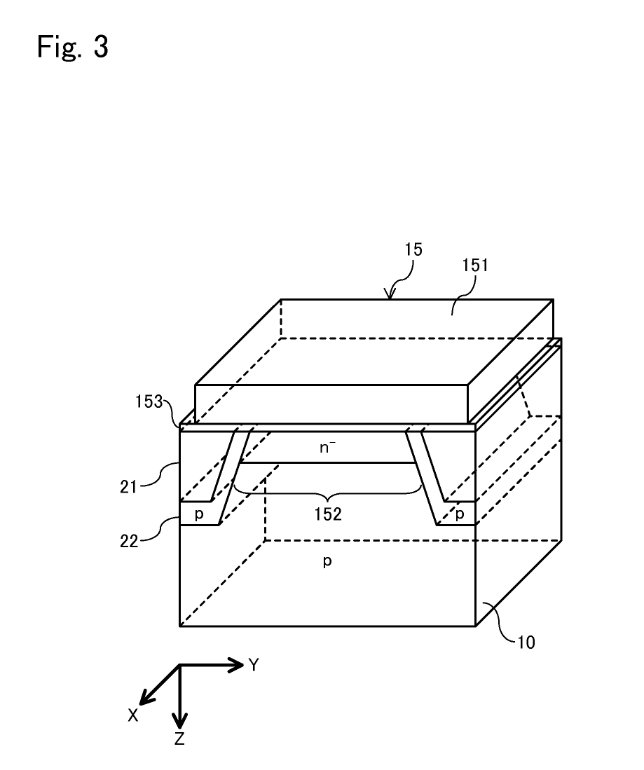

Next, an example of a structure of the source-follower transistor 15 shown in FIG. 2 and a surrounding thereof will be described with reference to the drawings. FIG. 3 is a main-part cross-sectional perspective view showing an example of the structure of the source-follower transistor and the surrounding thereof. In FIG. 3, a cross section perpendicular to the X direction of main parts of the source-follower transistor 15 and the surrounding thereof is shown as a front surface.

The source-follower transistor 15 includes a channel formation region 152 provided with a channel when the source-follower transistor 15 is set to the conducting state, the gate electrode 151, and a gate insulating film 153 that is formed on the surface of the substrate 10 and beneath the gate electrode 151.

The channel formation region 152 is a region which is provided by injecting an n-type impurity into the surface of the p-type substrate 10, and the channel formation region 152 includes an n-type (n⁻) region into which the n-type impurity is injected and a p-type region immediately below the n-type (n⁻) region. Further, a channel is formed near a boundary between the n-type (n⁻) region and the p-type region. That is, the source-follower transistor 15 becomes a buried-channel type transistor.

As described above, the element separator 21 is also provided near the portion where the buried channel is formed. Further, a surrounding region 22 of the element separator 21 (a side region extending from a sidewall of the element separator 21 to the Y direction, and a lower region extending from a bottom surface of the element separator 21 to the Z direction) is injected with a p-type impurity to become the p-type region.

It is preferable that a concentration of the p-type impurity injected into the surrounding region 22 of the element separator 21 (particularly, the side region) is at a level of canceling the n-type (n⁻) region included in the channel formation region 152. More specifically, it is preferable that the concentration of the p-type impurity injected into the surrounding region 22 of the element separator 21 (particularly, the side region) is at least two times a concentration of an n-type impurity injected into the n-type (n⁻) region included in the channel formation region 152.

For example, it is preferable that the concentration of the p-type impurity in the substrate 10 is 5×10¹⁶ cm⁻³ or more and 5×10¹⁷ cm⁻³ or less, the concentration of the n-type impurity in the n-type (n⁻) region included in the channel formation region 152 is 1×10¹⁷ cm⁻³ or more and 8×10¹⁷ cm⁻³ or less, the concentration of the p-type impurity in the surrounding region 22 of the element separator 21 is 5×10¹⁷ cm⁻³ or more and 5×10¹⁸ cm⁻³ or less, and a width of the surrounding region 22 of the element separator 21 (a length from the sidewall of the element separator 21) is about 50 nm.

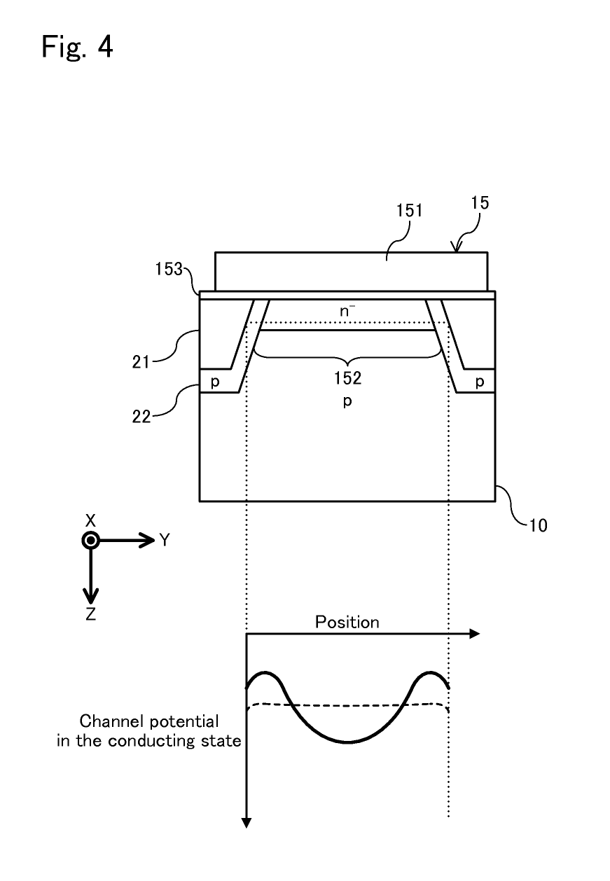

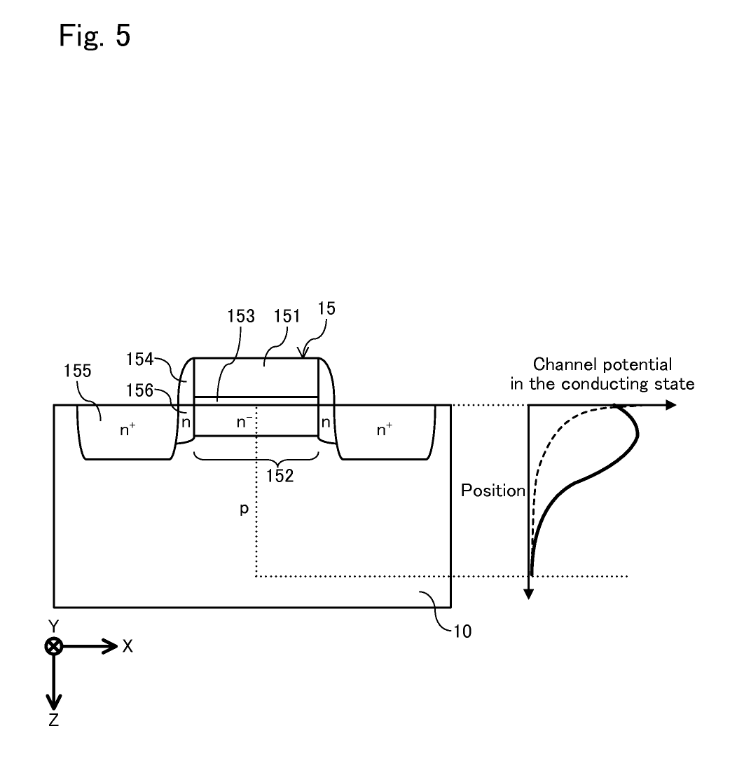

Next, the effects obtained by setting the source-follower transistor 15 to a structure shown in FIG. 3 will be described with reference to FIGS. 4 and 5. FIG. 4 is a cross-sectional view showing a cross section perpendicular to the X direction of the source-follower transistor. FIG. 5 is a cross-sectional view showing a cross section perpendicular to the Y direction of the source-follower transistor.

In FIGS. 4 and 5, graphs showing variations of a channel potential along predetermined directions (the Y direction in FIG. 4, and the Z direction in FIG. 5) in the conducting state of the source-follower transistor 15 are displayed together with the cross-sectional views. Further, as the graphs, not only the graphs of the source-follower transistor 15 (thick solid lines in the figures), but also graphs of a conventional source-follower transistor for comparison (broken lines in the figures) (structures in which the n-type impurity is not injected into the channel formation region 152, and the p-type impurity is not injected into the surrounding region 22 of the element separator 21) are displayed. A region where a channel potential in the conducting state is higher (a front end side of an arrow) is a region where electrons can stably exist (a channel can be formed).

As shown in FIG. 5, the source-follower transistor 15 includes sidewalls 154 that are provided at both ends in the X direction of the gate electrode 151, n-type (n⁺) diffusion regions 155 that are formed on a surface side of the substrate 10 and that constitute a source and a drain respectively, and n-type thin diffusion region 156 that are formed on the surface side of the substrate 10 and immediately below the sidewalls 154 and that are respectively connected to the diffusion regions 155. That is, the source-follower transistor 15 has an LDD (Lightly Doped Drain) structure.

As shown in FIG. 4, in the conventional source-follower transistor, a channel potential in the conducting state varies little along the Y direction and also becomes slightly higher near the element separator 21. Therefore, there is formed a channel that extends to the element separator 21. Consequently, due to the influence of the level of the interface of the element separator 21, much 1/f noise is included in the signal output from the conventional source-follower transistor.

On the other hand, as shown in FIG. 4, in the source-follower transistor 15, the channel potential in the conducting state becomes the lowest near the surrounding region 22 of the element separator 21, and becomes higher with increasing distance from the element separator 21. Therefore, a buried channel is formed in a region away from the element separator 21 (particularly, a center portion in the Y direction of the channel formation region 152). Consequently, the 1/f noise is effectively reduced from the signal output from the source-follower transistor 15.

As shown in FIG. 5, in the conventional source-follower transistor, the channel potential in the conducting state gradually becomes low with increasing distance from the surface of the substrate 10 along the Z direction. Therefore, a channel is formed near the gate insulating film 153 where the channel potential in the conducting state becomes the highest. Consequently, due to the influence of the level of the interface of the gate insulating film 153, much 1/f noise is included in the signal output from the conventional source-follower transistor.

On the other hand, as shown in FIG. 5, in the source-follower transistor 15, the channel potential in the conducting state becomes the highest in a region away from the surface of the substrate 10 by a predetermined distance (particularly, near a boundary between the n-type (n⁻) region included in the channel formation region 152 and the p-type region immediately below the n-type (n⁻) region). Therefore, a buried channel is formed in a region away from a gate insulating film 153. Consequently, the 1/f noise is effectively reduced from the signal output from the source-follower transistor 15.

As described above, in the solid-state imaging element according to the embodiment of the present invention, a buried channel away from the sidewall of the element separator 21 is formed in the source-follower transistor 15. Therefore, by suppressing the influence of the level of the interface of the gate insulating film 153 and the interface of the element separator 21, it is possible to effectively reduce the 1/f noise from the signal output from the source-follower transistor 15.

Further, it is preferable to suppress spreading of the channel formation region 152 by cancelling the n-type (n⁻) region included in the channel formation region 152, by controlling the concentration of the p-type impurity injected into the surrounding region 22 (particularly, the side region) of the element separator 21. In this case, it is possible to accurately form the buried channel away from the sidewall of the element separator 21. Further, because the p-type impurity is injected into the surrounding region 22 of the element separator 21, it is possible to suppress generation of a dark current in the photodiode 11.

It is more preferable that the concentration of the p-type impurity injected into the surrounding region 22 of the element separator 21 (particularly, the side region) is at least two times the concentration of the n-type impurity injected into the n-type (n⁻) region included in the channel formation region 152. In this case, the buried channel away from the sidewall of the element separator 21 can be formed more accurately.

As described above, when the channel formed in the source-follower transistor 15 is a buried channel, a short-channel effect (for example, occurrence of punch-through due to approach of a depletion layer in each of the source and the drain) becomes significant. Therefore, it is preferable that a distance between the source and the drain of the source-follower transistor 15 is set as large as possible in terms of design, as shown in FIG. 2. Further, as described above, the 1/f noise decreases with increase in the gate capacitance. Consequently, this structure is preferable because the structure can suppress the 1/f noise.

<Method of Injecting p-Type Impurity into Surrounding Region of Element Separator>

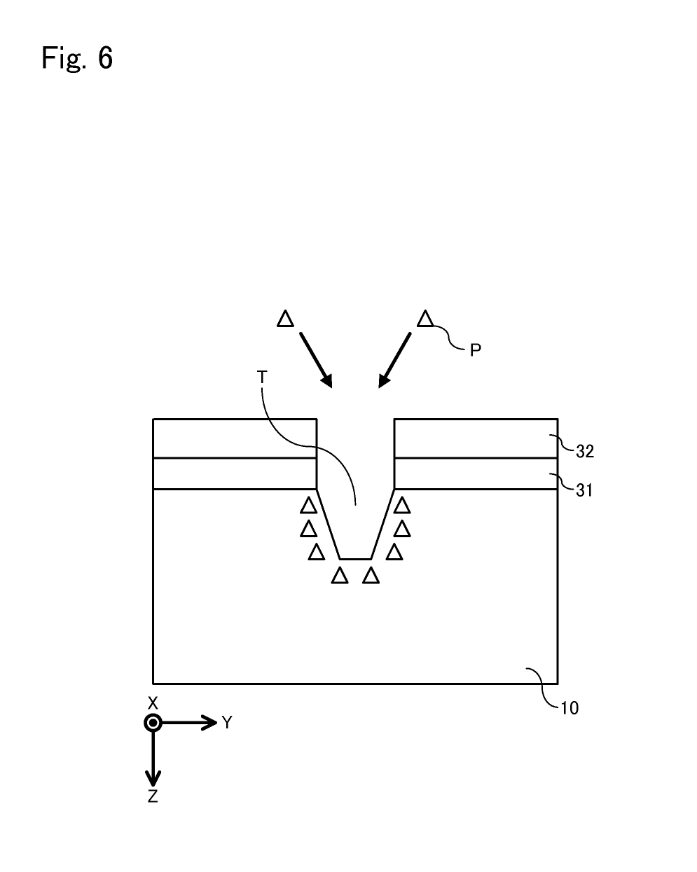

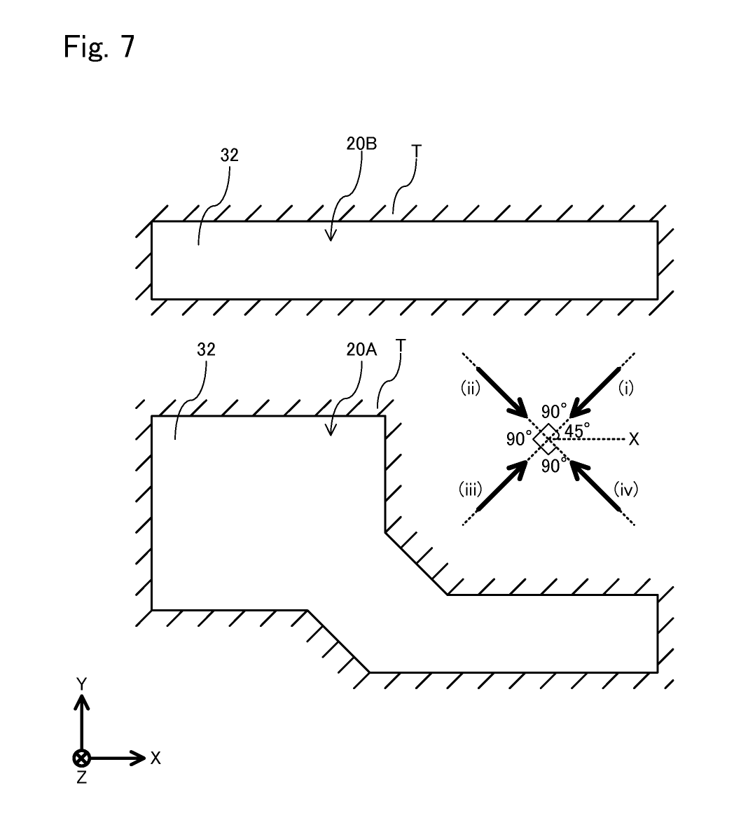

Next, an example of a method of injecting the p-type impurity into the surrounding region 22 of the element separator 21 will be described with reference to the drawings. FIG. 6 is a cross-sectional view of a substrate showing an example of the method of injecting the p-type impurity into the surrounding region of the element separator. FIG. 7 is a plan view of the substrate showing the example of the method of injecting the p-type impurity into the surrounding region of the element separator. The cross section shown in FIG. 6 is perpendicular to the X direction. The plane shown in FIG. 7 is perpendicular to the Z direction, and is the substrate 10 shown in FIG. 6 seen from the surface side. A trench T can be formed on the whole substrate excluding the active regions 20A and 20B, and particularly in FIG. 7, portions formed near the active regions 20A and 20B are shown by hatched lines.

As shown in FIG. 6, in the method of injecting the p-type impurity in this example, after forming the trench T on the substrate 10, the p-type impurity P is injected before burying the trench T with a material forming the element separator 21. At this time, as shown in FIG. 6, the p-type impurity P is injected into the surface of the substrate 10 excluding the portion in which the trench T is formed, in a state where a mask layer 31 and a resist 32 which are used to form the trench T being left. The mask layer 31 is composed of oxide or nitride, for example.

In this case, the p-type impurity P can be injected into the active region 20 by accurate positioning (alignment). Therefore, a gate capacitance becomes large because a concentration distribution of the p-type impurity P becomes steep, and it is possible to effectively reduce the 1/f noise.

As shown in FIG. 6, in the method of injecting the p-type impurity P in this example, the p-type impurity P is injected from an injection direction inclined by a predetermined angle (7 degrees or more and 30 degrees or less, for example) to the Z direction.

As described above, when the p-type impurity P is injected from an injection direction inclined to the Z direction, the p-type impurity P can be efficiently injected into the surrounding region 22 of the element separator 21 (particularly, the side region). In addition to this injection direction, the p-type impurity P may also be injected from the injection direction parallel to the Z direction. In this case, the p-type impurity P can be efficiently injected into the side region at a deep position from the surface of the substrate 10 and the lower region. As described above, the angle of the injection direction inclined to the Z direction is not limited to one, but a plurality of inclination angles may be used.

Further, as shown in FIG. 7, in the method of injecting the p-type impurity P in this example, the injection direction of the p-type impurity P is also inclined in the plane perpendicular to the Z direction. For example, the injection direction of the p-type impurity P is in four injection directions (arrows (i) to (iv) in the figure) inclined by 45 degrees to the X direction and the Y direction, respectively.

Specifically, in the plane perpendicular to the Z direction, an injection direction (ii) is inclined by 90 degrees to an injection direction (i), an injection direction (iii) is inclined by 90 degrees to the injection direction (ii) and inclined by 180 degrees to the injection direction (i), and an injection direction (iv) is inclined by 90 degrees to the injection direction (iii) and inclined by 180 degrees to the injection direction (ii).

In this way, in the plane perpendicular to the Z direction, when the p-type impurity P is injected from a plurality of directions, the p-type impurity P can be uniformly injected into the surrounding region 22 of the element separator 21 (particularly, the side region). As shown in FIG. 7, it is preferable that an opposite injection direction (inclined by 180 degrees) is set or inclinations among injection directions are set equal, so that the p-type impurity P can be more uniformly injected. Although four injection directions are set in the example shown in FIG. 7, other numbers of injection directions (for example, two or eight) may be employed.

As described above, a moving direction of electrons in the transfer transistor 12 is different from that in other transistors 14 to 16 (see FIG. 2). With such a structure, it is possible to partially control the concentration of the p-type impurity P to be injected by appropriately selecting the injection direction of the p-type impurity.

Specifically, for example, when an injection direction parallel to the moving direction of the electrons in the transfer transistor 12 is selected (see FIG. 7), the concentration of the p-type impurity P injected into the surrounding region 22 of the element separator 21 (particularly, the side region) provided around the transfer transistor 12 can be reduced.

The transfer transistor 12 needs to be made small in size, and carriers generated in the photodiode 11 need to be accurately transferred to the floating diffusion region 13. Therefore, it is preferable that a surface channel having little problem of occurrence of a short-channel effect and the like is formed, and the concentration of the injected p-type impurity P is reduced.

<Transistors Other than Source-Follower Transistor>

Transistors other than the transfer transistor 12, that is, the reset transistor 14 and the selection transistor 16 may have structures similar to that of the source-follower transistor 15 (including other example described later). Specifically, for the reset transistor 14 and the selection transistor 16, the n-type buried channel may be formed by injecting an n-type impurity into the surface of the substrate 10 immediately below the gate electrodes 141 and 161 (see FIGS. 3 to 5).

Particularly, in the reset transistor 14, reset noise may be generated due to variation in a threshold voltage caused by injection of the p-type impurity P into the surrounding region 22 of the element separator 21. Therefore, in the reset transistor 14, it is preferable that the threshold voltage is adjusted by injecting an n-type impurity similarly to the source-follower transistor 15 to suppress the reset noise. By the injection of the n-type impurity, the reset transistor 14 may become a depletion type transistor. Even in this case, by appropriately adjusting the potential applied to the back gate or the like, the reset transistor 14 can be set to the non-conducting state in a desired bias state.

In the case of setting the reset transistor 14 and the selection transistor 16 to structures similar to that of the source-follower transistor 15, a manufacturing process of a solid-state imaging element can be facilitated by simultaneously forming these transistors 14 to 16.

<<Modifications>>

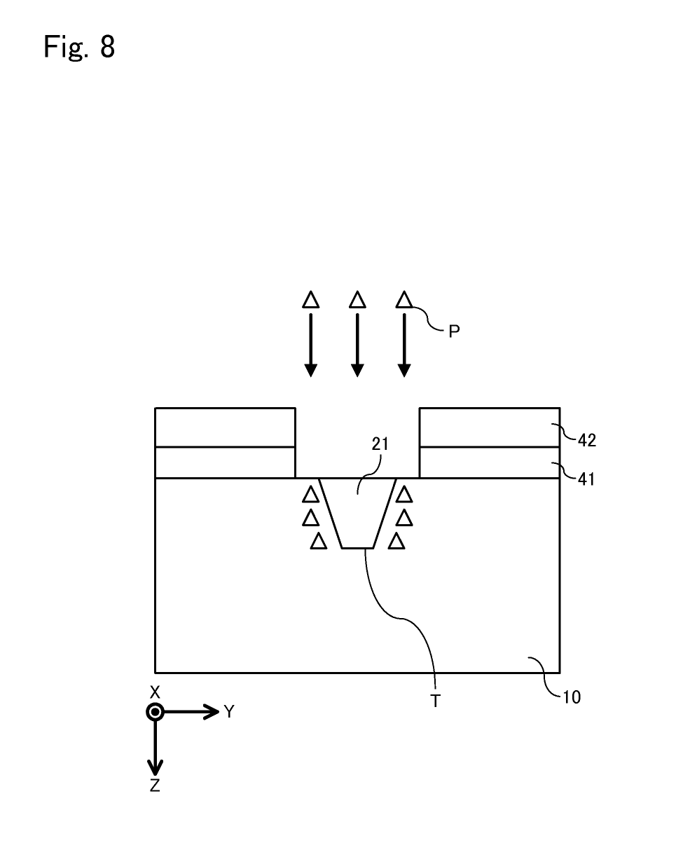

An injection method described below may be performed in addition to (or instead of) the above method of injecting the p-type impurity P into the surrounding region 22 of the element separator 21 (see FIGS. 6 and 7). The injection method will be described with reference to FIG. 8. FIG. 8 is a cross-sectional view of a substrate showing another example of the method of injecting the p-type impurity into the surrounding region of the element separator. A cross section shown in FIG. 8 is perpendicular to the X direction.

In the method of injecting the p-type impurity P shown in FIG. 8, the p-type impurity P is injected after the trench T is buried with a material forming the element separator 21. Further, a mask layer 41 and a resist 42 are formed so that the end part recedes from a position immediately above the trench T (the element separator 21), and the p-type impurity P is injected from an injection direction parallel to the Z direction. The mask layer 41 is composed of an oxide or a nitride, for example.

In this injection method, because the mask layer 41 and the resist 42 are formed again after the p-type impurity P is injected, accuracy of positioning (alignment) with respect to the active region 20 may become poor to some extent. However, the injection of the p-type impurity P can be shifted to a later stage of the method of manufacturing the solid-state imaging element. Therefore, unintended diffusion of the injected p-type impurity P by a heat treatment and the like included in the manufacturing process can be suppressed.

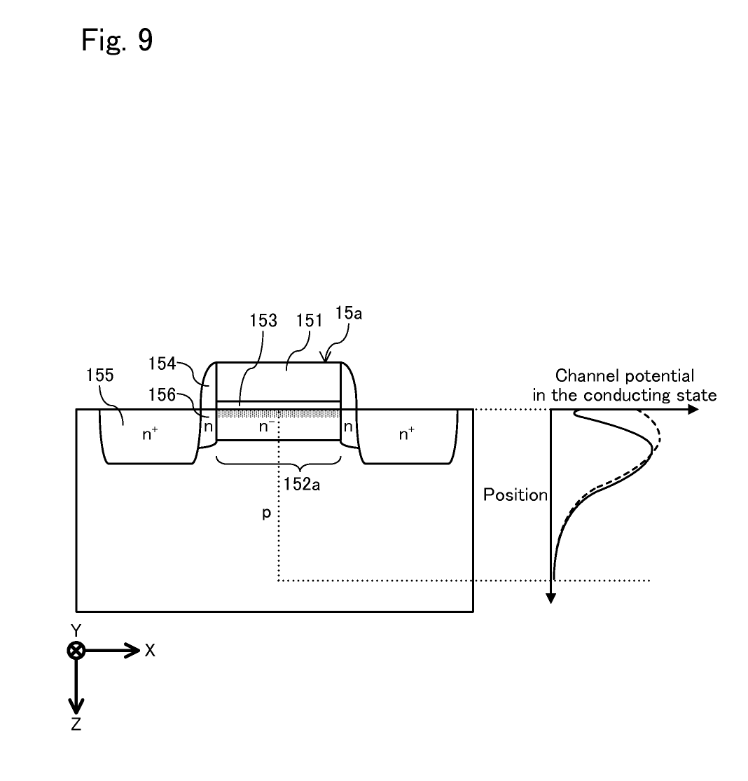

Although it has been described that the channel formation region 152 is formed by injecting an n-type impurity into the surface of the p-type substrate 10 (see FIG. 5), a p-type impurity may be further injected into this surface. A structure in this case and obtained effects will be described with reference to FIG. 9. FIG. 9 is a cross-sectional view showing another example of a structure of a source-follower transistor. A cross section shown in FIG. 9 is perpendicular to the Y direction, and a source-follower transistor 15a in this example is represented in a similar manner as in FIG. 5. However, in FIG. 9, a graph of the source-follower transistor 15a (a solid line in the figure), and a graph of the source-follower transistor 15 (a broken line in the figure) shown in FIG. 5 for comparison are displayed together.

As shown in FIG. 9, the source-follower transistor 15a has a p-type impurity (a gray region in the figure) injected into a surface of a channel formation region 152a. Other structures are similar to those of the source-follower transistor 15 shown in FIG. 5, and therefore, descriptions thereof will be omitted.

With such a structure, a channel potential in a conducting state near the surface of the substrate 10 becomes lower, and a position at which the channel potential in the conducting state is the highest becomes deeper. That is, in the source-follower transistor 15a shown in FIG. 9, there can be formed a buried channel which is more effectively buried as compared with the source-follower transistor 15 shown in FIG. 5.

At the time of forming the channel formation region 152a of the source-follower transistor 15a shown in FIG. 9, for example, it is preferable that the n-type impurity is injected at the acceleration energy of 70 keV or more and 140 keV or less, and the p-type impurity is injected at the acceleration energy of 10 keV or more and 20 keV or less. In this case, for example, a peak position of a concentration distribution of the n-type impurity becomes 0.02 μm or more and 0.12 μm or less at a depth from the surface of the substrate 10, and a peak position of a concentration distribution of the p-type impurity becomes 0.00 μm or more and 0.02 μm or less at a depth from the surface of the substrate 10. That is, an ideal structure as shown in FIG. 9 is obtained.

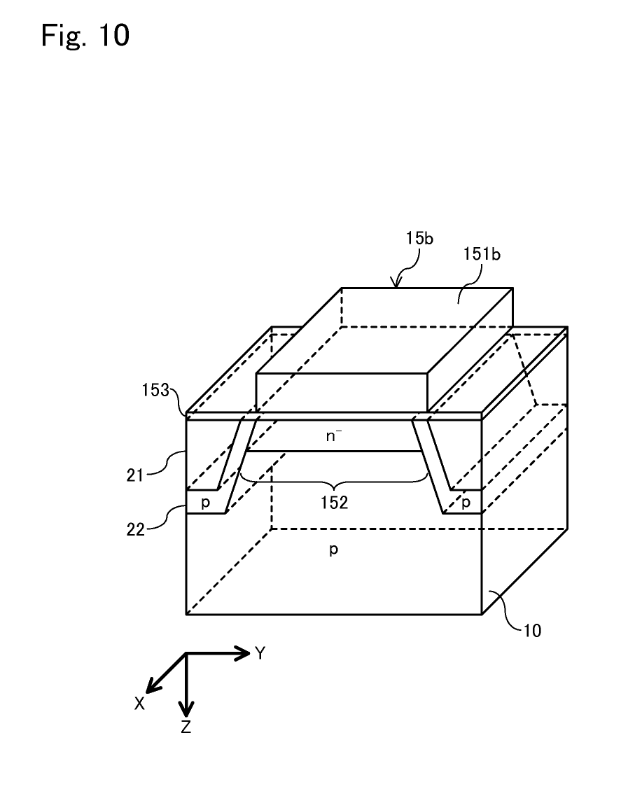

In FIGS. 2 to 4, although the end part of the gate electrode 151 is illustrated to extend to a position immediately above the element separator 21, the end part may recede from the position immediately above the element separator 21. This structure will be described with reference to FIG. 10. FIG. 10 is a main-part cross-sectional perspective view showing another example of the structure of the source-follower transistor. FIG. 10 is similar to FIG. 3, and a cross section perpendicular to the X direction of main parts of a source-follower transistor 15b and a surrounding thereof is shown as a front surface.

As shown in FIG. 10, in the source-follower transistor 15b, the end part of the gate electrode 151b recedes from the position immediately above the element separator 21. Other structures are similar to those of the source-follower transistor 15 shown in FIG. 3, and therefore, descriptions thereof will be omitted.

With such a structure, since a potential applied to the gate electrode 151b is hardly applied to the vicinity of the element separator 21, a buried channel to be formed hardly spreads to the vicinity of the element separator 21. Therefore, it is possible to effectively reduce the 1/f noise.

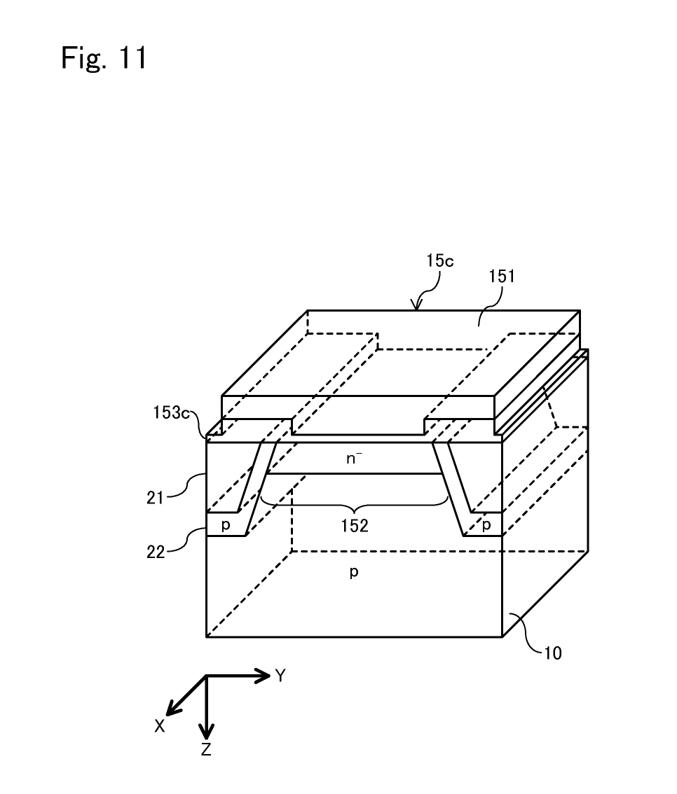

In FIGS. 2 to 4, although the thickness of the gate insulating film 153 is illustrated to be uniform, the thickness may be partially large. This structure will be described with reference to FIG. 11. FIG. 11 is a main-part cross-sectional perspective view showing another example of the structure of the source-follower transistor. FIG. 11 is similar to FIG. 3, and a cross section perpendicular to the X direction of main parts of a source-follower transistor 15c and a surrounding thereof is shown as a front surface.

As shown in FIG. 11, in the source-follower transistor 15c, a thickness of a portion near the element separator 21 of a gate insulating film 153c is larger than a thickness of a portion away from the element separator 21 (a portion immediately below the gate electrode 151). Other structures are similar to those of the source-follower transistor 15 shown in FIG. 3, and therefore, descriptions thereof will be omitted.

With such a structure, since a potential applied to the gate electrode 151 is hardly applied to the vicinity of the element separator 21, a buried channel to be formed hardly spreads to the vicinity of the element separator 21. Therefore, it is possible to effectively reduce the 1/f noise.

Although the case where the selection transistor 16 is disposed between the signal line 17 and the source-follower transistor 15 has been described, the selection transistor 16 may be disposed between the power supply potential VDD and the source-follower transistor 15, or may not be provided. In the case of disposing the selection transistor 16 between the power supply potential VDD and the source-follower transistor 15, the power supply potential VDD may be supplied to the drain of the selection transistor 16, the source of the selection transistor 16 may be shared with the drain of the source-follower transistor 15, and the source of the source-follower transistor 15 may be connected to the signal line 17.

In FIGS. 3, 4, 10, and 11, although it is illustrated that the p-type impurity is injected into each of the side region and the lower region which constitute the surrounding region 22 of the element separator 21, the p-type impurity may be injected only into the side region and the p-type impurity may not be injected into the lower region.

Although the case where the element separator 21 is an STI has been illustrated, the element separator 21 may have other structure such as LOCOS (local oxidation of silicon). However, in the case of a structure that extends in a depth direction of the substrate 10 like the STI, it is highly necessary to suppress spreading of the buried channel. Therefore, the effect of reducing the 1/f noise obtained by employing the above structure becomes large.

In the photodiode 11, a p-type pinning layer may be provided on an outermost surface of an n-type accumulation region. By providing the p-type pinning layer, it is possible to suppress disappearance of electrons as carriers due to recombination on the surface.

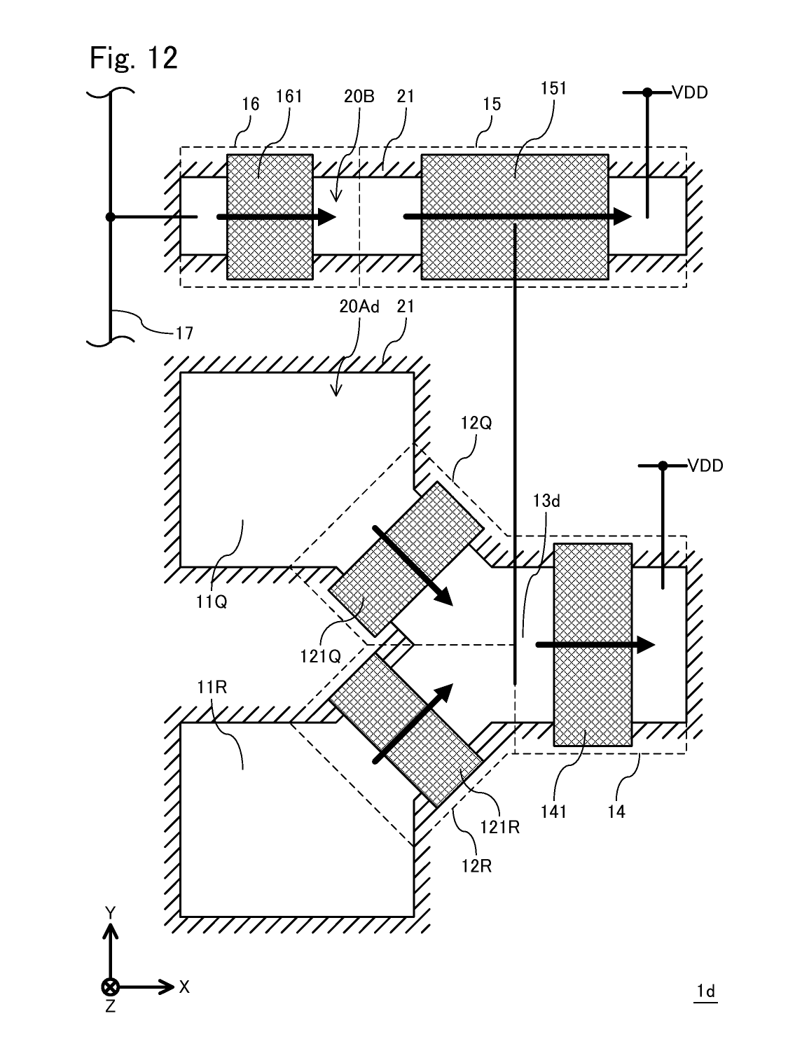

Although the configuration has been illustrated in which one pixel circuit 1 includes one source-follower transistor 15, a plurality of pixel circuits may share one source-follower transistor 15. Alternatively, one pixel circuit may be provided with a plurality of photodiodes. A structure example of the latter pixel circuit will be described with reference to FIG. 12. FIG. 12 is a schematic plan view showing another example of the schematic structure of the pixel circuit. FIG. 12 illustrates the pixel circuit in the same manner as in FIG. 2. To simplify the description, in a pixel circuit ld shown in FIG. 12, portions different from those of the pixel circuit 1 shown in FIG. 2 will be mainly described, and descriptions of similar portions will be omitted.

As shown in FIG. 12, the pixel circuit ld includes two photodiodes 11Q and 11R, and two transfer transistors 12Q and 12R. A source of the transfer transistor 12Q is connected to a cathode of the photodiode 11Q, and a source of the transfer transistor 12R is connected to a cathode of the photodiode 11R. A shared floating diffusion region 13d is connected to respective drains of the transfer transistors 12Q and 12R. Other structures of the pixel circuit ld are similar to those of the pixel circuit 1 shown in FIG. 2. Further, the photodiodes 11Q and 11R, the transfer transistors 12Q and 12R, the floating diffusion region 13, and the reset transistor 14 are provided in a shared active region 20Ad.

The transfer transistors 12Q and 12R are disposed side by side along the Y direction, and moving directions of electrons in the transfer transistors 12Q and 12R are different from the X direction and are symmetrical with the X direction. In the example shown in FIG. 12, the moving direction of the electrons in the transfer transistor 12Q is inclined by 45 degrees to the X direction, and the moving direction of the electrons in the transfer transistor 12R is inclined by −45 degrees to the X direction (when a clockwise angle is defined as a positive angle).

In the pixel circuit 1d, the electrons accumulated in the photodiodes 11Q and 11R are alternately read out to the floating diffusion region 13d. That is, the floating diffusion region 13, the reset transistor 14, the source-follower transistor 15, and the selection transistor 16 are shared by the two photodiodes 11Q and 11R and the two transfer transistors 12Q and 12R. Therefore, a scale of a circuit necessary for obtaining a signal from one photodiode can be reduced. Consequently, areas of the photodiodes 11Q and 11R can be made large.

Although the configuration has been illustrated in which the transfer transistor 12 and the reset transistor 14 are connected by sharing the floating diffusion region 13, the reset transistor 14 and the floating diffusion region 13 may be connected by wiring, for example.

The case has been illustrated where the pixel circuits 1 and 1d are formed by providing, on the p-type substrate 10, the photodiode 11 having the n-type accumulation region, and the transistors 12, and 14 to 16 provided with the n-type channel (the case where carriers are electrons). However, the p-type and the n-type may be opposite (carriers may be holes).

### INDUSTRIAL APPLICABILITY

A solid-state imaging element according to the present invention may be suitably applied to a CMOS image sensor and the like that are mounted on various electronic devices having an imaging function, for example.

### EXPLANATION OF REFERENCES

1 pixel circuit
10 substrate
11 photodiode
12 transfer transistor
121 gate electrode
13 floating diffusion region
14 reset transistor
141 gate electrode
15 source-follower transistor
151 gate electrode
152 channel formation region
153 gate insulating film
154 sidewall
155 diffusion region
156 thin diffusion region
16 selection transistor
161 gate electrode
17 signal line
20 active region
21 element separator
22 surrounding region
31 mask layer
32 resist
41 mask layer
42 resist
P p-type impurity
T trench

1. A solid-state imaging element comprising:
a first conductivity type substrate;
a photodiode which is formed on the substrate, and in which carriers generated by photoelectric conversion are accumulated in a second conductivity type accumulation region, the second conductivity type being different from the first conductivity type;
a source-follower transistor which is formed on the substrate, and which has a gate electrode electrically connected to a floating diffusion region accumulated with the carriers read out from the photodiode and which is provided with a second conductivity type buried channel; and
an element separator which is formed on the substrate, and which is provided around an active region of at least the photodiode and the source-follower transistor, wherein
the buried channel of the source-follower transistor is formed away from a sidewall of the element separator,
the buried channel of the source-follower transistor is formed within a channel formation region provided by injecting a second conductivity type impurity into a surface of the first conductivity type substrate,
a concentration of a first conductivity type impurity injected into a side region of the element separator is at a level of canceling a second conductivity type region included in the channel formation region, and
the first conductivity type impurity is injected into an outermost surface of the channel formation region of the source-follower transistor.

2. (canceled)

3. The solid-state imaging element according to claim 1, wherein the concentration of the first conductivity type impurity injected into the side region of the element separator is at least two times the concentration of the second conductivity type impurity injected into the second conductivity type region included in the channel formation region of the source-follower transistor.

4. (canceled)

5. The solid-state imaging element according to claim 1, wherein the first conductivity type impurity is also injected into a lower region of the element separator.

6. The solid-state imaging element according to claim 3, further comprising:
a transfer transistor which is formed on the substrate, and which has the accumulation region as a source and the floating diffusion region as a drain; and
a reset transistor which is formed on the substrate, and which has the floating diffusion region as a source and a predetermined potential as a drain.

7. The solid-state imaging element according to claim 6, wherein the reset transistor is provided with a second conductivity type buried channel.

8. The solid-state imaging element according to claim 6, wherein a separation direction of the source and the drain of the transfer transistor is different from a separation direction of the source and the drain of the source-follower transistor.

9. The solid-state imaging element according to claim 1, further comprising:
a selection transistor in which the drain is shared with the source of the source-follower transistor or the source is shared with the drain of the source-follower transistor.

10. The solid-state imaging element according to claim 9, wherein the selection transistor is provided with a second conductivity type buried channel.

11. The solid-state imaging element according to claim 1, wherein the element separator is an STI including at least one of an oxide and a nitride.

12. The solid-state imaging element according to claim 1, wherein a gate electrode of at least one transistor provided with the buried channel is formed such that an end part of the gate electrode recedes from a position immediately above the element separator.

13. The solid-state imaging element according to claim 1, wherein a gate insulating film that is provided immediately below a gate electrode of at least one transistor provided with the buried channel is formed such that a thickness of a portion near the element separator is larger than a thickness of a portion away from the element separator.

14. The solid-state imaging element according to claim 5, further comprising:
a transfer transistor which is formed on the substrate, and which has the accumulation region as a source and the floating diffusion region as a drain; and
a reset transistor which is formed on the substrate, and which has the floating diffusion region as a source and a predetermined potential as a drain.

15. The solid-state imaging element according to claim 14, wherein the reset transistor is provided with a second conductivity type buried channel.

16. The solid-state imaging element according to claim 14, wherein a separation direction of the source and the drain of the transfer transistor is different from a separation direction of the source and the drain of the source-follower transistor.

17. The solid-state imaging element according to claim 1, further comprising:
a transfer transistor which is formed on the substrate, and which has the accumulation region as a source and the floating diffusion region as a drain; and
a reset transistor which is formed on the substrate, and which has the floating diffusion region as a source and a predetermined potential as a drain.

18. The solid-state imaging element according to claim 17, wherein the reset transistor is provided with a second conductivity type buried channel.

19. The solid-state imaging element according to claim 17, wherein a separation direction of the source and the drain of the transfer transistor is different from a separation direction of the source and the drain of the source-follower transistor.
